(19) United States
(12) Patent Application Publication
(10) Pub. No.: US 2012/0276668 A1
(43) Pub. Date: Nov. 1, 2012

(54) METHOD FOR MANUFACTURING SEMICONDUCTOR LIGHT EMITTING DEVICE

(75) Inventor: Eiji Muramoto, Kanagawa-ken (JP)

(73) Assignee: KABUSHIKI KAISHA TOSHIBA, Tokyo (JP)

(21) Appl. No.: 13/234,778

(22) Filed: Sep. 16, 2011

(30) Foreign Application Priority Data
Apr. 27, 2011 (JP) 2011-099732

(51) Int. Cl. H01L 33/08

(52) U.S. Cl. 438/28; 257/E33.073

(57) ABSTRACT

In one embodiment, a method is disclosed for manufacturing a semiconductor light emitting device. The method can include forming a plurality of light emitting regions on a major surface of a support substrate. The method can include forming V-shaped grooves by anisotropic etching between the plurality of light emitting regions in the major surface of the support substrate. In addition, the method can include dividing the support substrate at positions of the grooves to separate the light emitting regions.

### CROSS-REFERENCE TO RELATED APPLICATIONS

This application is based upon and claims the benefit of priority from the prior Japanese Patent Application No. 2011-099732, filed on Apr. 27, 2011; the entire contents of which are incorporated herein by reference.

### FIELD

Embodiments described herein relate generally to a method for manufacturing a semiconductor light emitting device.

### BACKGROUND

In semiconductor light emitting devices such as Light Emitting Diodes (LEDs), techniques for forming a stacked body that includes light emitting layers on a substrate are used. In semiconductor light emitting devices, light extraction efficiency is improved by performing concave-convex processing on light emitting surfaces (extraction surfaces). In semiconductor light emitting devices of this type, further increases in reliability and in manufacturing yield are desired.

### BRIEF DESCRIPTION OF THE DRAWINGS

FIGS. 1A to 4D are schematic cross-sectional views illustrating a method for manufacturing a semiconductor light emitting device according to a first embodiment;

FIGS. 5A and 5B are schematic views illustrating the grooves;

FIG. 6 is a schematic cross-sectional view illustrating a semiconductor light emitting device;

FIGS. 7A to 8C are schematic cross-sectional views illustrating a method for manufacturing a semiconductor light emitting device according to a second embodiment; and

FIGS. 9A to 12 are schematic cross-sectional views illustrating a method for manufacturing a semiconductor light emitting device according to a third embodiment.

### DETAILED DESCRIPTION

In general, according to one embodiment, a method is disclosed for manufacturing a semiconductor light emitting device. The method can include forming a plurality of light emitting regions on a major surface of a support substrate. The method can include forming V-shaped grooves by anisotropic etching between the plurality of light emitting regions in the major surface of the support substrate. In addition, the method can include dividing the support substrate at positions of the grooves to separate the light emitting regions.

Various embodiments will be described hereinafter with reference to the accompanying drawings.

Note that the drawings are schematic or conceptual in nature, and relationships between thicknesses and widths of each portion, ratios between sizes of portions and the like are not therefore necessarily identical to the actual relationships and ratios. Also, even where identical portions are depicted, dimensions and ratios may appear differently depending on the drawing.

Further, in the drawings and specification of the application, the same numerals are applied to elements that have already appeared in the drawings and been described, and repetitious detailed descriptions of such elements are omitted.

Also, in the following description, examples are given as examples wherein a first conductivity type is n-type, and a second conductivity type is p-type.

### First Embodiment

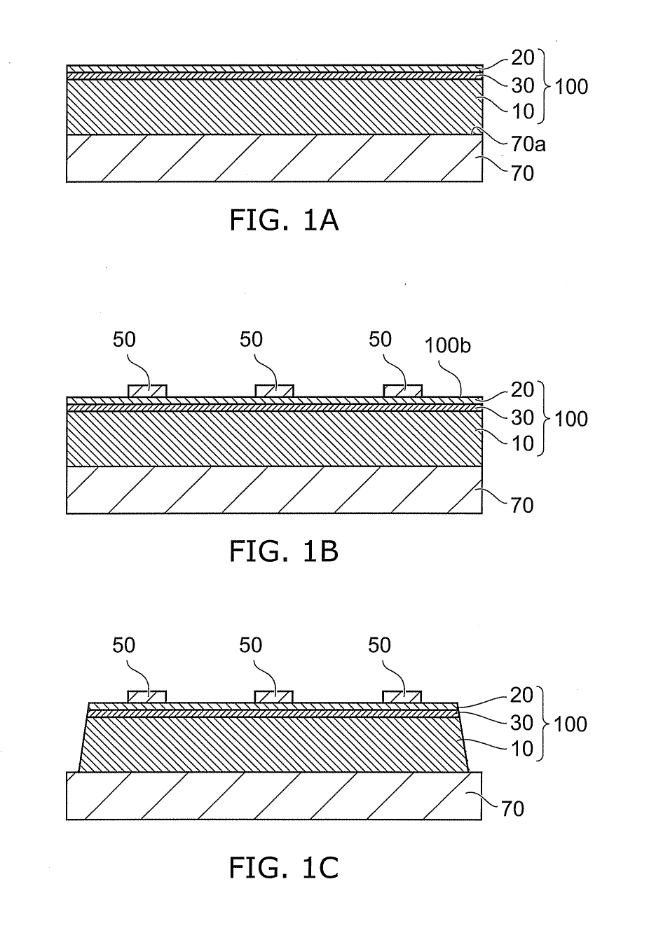

FIGS. 1A to 4D are schematic cross-sectional views illustrating a method for manufacturing a semiconductor light emitting device according to a first embodiment.

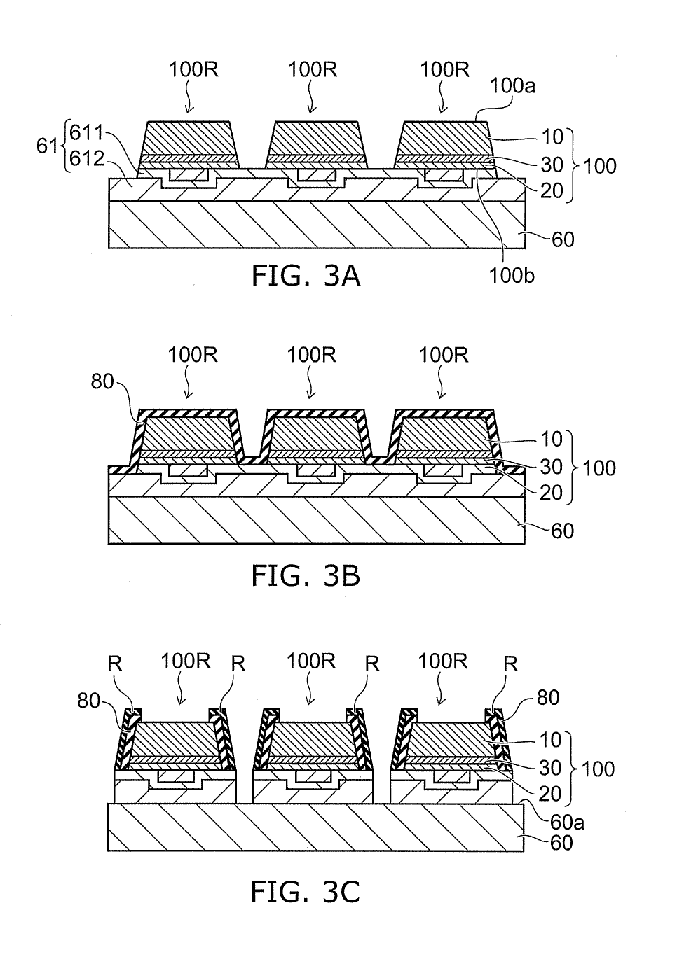

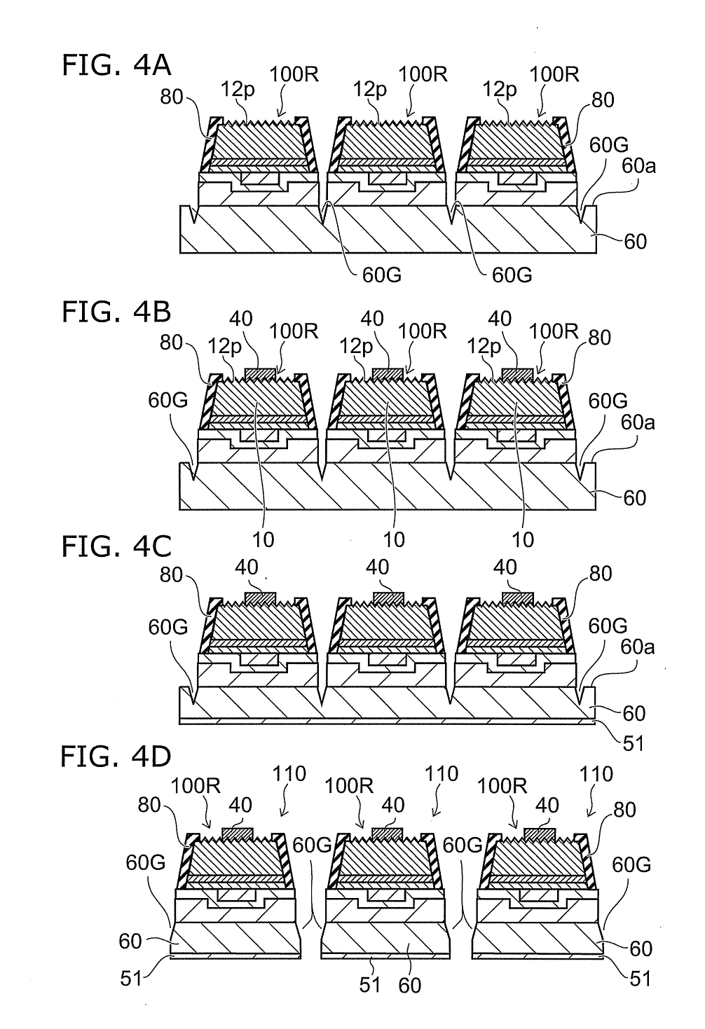

The manufacturing method according to the embodiment includes: as shown in FIG. 3C, a process for forming a plurality of light emitting regions 100R on a major surface 60a of a support substrate 60; as shown in FIG. 4A, a process for forming V-shaped grooves 60G by anisotropic etching between the plurality of light emitting regions 100R in the main surface 60a of the support substrate 60; and as shown in FIG. 4D, a process for dividing the support substrate 60 at positions of the grooves 60G and separating the support substrate 60 into respective light emitting regions 100R.

In the embodiment, a substrate including silicon is used as the support substrate 60. For the anisotropic etching, wet etching with, for example, an alkaline solution is used. Hence, the grooves 60G are formed with a V-shape having an angle based on a plane orientation of the silicon. As a result of the grooves 60G being formed in the support substrate 60, the support substrate 60 is divided by breaking originated at the positions of the grooves 60G.

Further, in the embodiment, concave and convex portions 12p are formed on the surface of the light emitting region 100R by anisotropic etching. Forming the concave and convex portions 12p on the surface of the light emitting region 100R improves the extraction efficiency for light emitted from the light emitting region 100R to the exterior. In the embodiment, the grooves 60G in the support substrate 60 are formed by the anisotropic etching that is used when forming the concave and convex portions 12p. Hence, the formation of the concave and convex portions 12p and the formation of the grooves 60G can be performed in one process without using a separate process, and a simplification of the manufacturing process can be achieved.

Next, the specific manufacturing method is described in detail based on FIGS. 1A to 4D.

First, as shown in FIG. 1A, after forming a buffer layer (not shown) on a major surface 70a of a growth-use substrate 70 made of sapphire, a stacked body 100 including a first semiconductor layer 10, a light emitting layer 30 and a second semiconductor layer 20 is grown by crystalline growth.

The stacked body 100 is formed using, for example, an organic metal phase growth method. As an example, the stacked body 100 is formed using a nitride semiconductor described below.

In the specification, “nitride semiconductor” is used to mean semiconductors defined by the chemical formulae InₓAl_{y}Ga_{1-x-y}N (where 0≦x≦1, 0≦y≦1, x+y≦1) or BₓIn_{y}Al_{z}Ga_{1-x-y-z}N (where 0≦x≦1, 0≦y≦1, 0≦z≦1, x+y+z≦1) and includes all composition ratios within the specified ranges for x, y and z. Furthermore, for the formulae described above, “nitride semiconductors” are also understood to include semiconductors further including group V elements other than N (nitrogen), semiconductors further including various elements added to control physical properties such as conductivity type and the like, and semiconductors further including various unintentionally included elements.

First, a first AlN buffer layer with a high carbon concentration (of, for example, not less than 3×10¹⁸ cm⁻³ and not more than 5×10²⁰ cm⁻³, and a thickness of, for example, not less than 3 nm and not more than 20 nm), a second AlN buffer layer of high purity (with a carbon concentration of, for example, not less than 1×10¹⁶ cm⁻³ and not more than 3×10¹⁸ cm⁻³, and a thickness of 2 μm), and a non-doped GaN buffer layer (with a thickness of, for example, 2 μm) are formed in this order as buffer layers on a growth-use substrate 70, which has a surface made of a sapphire c face. The above-described first and second AlN buffer layers are monocrystalline aluminum nitride layers. By using monocrystalline aluminum nitride layers as the first and second AlN buffer layers, high-quality semiconductor layers can be formed in the later-described crystalline growth and damage to the crystals is substantially reduced.

Next, a silicon (Si) doped n-type GaN contact layer (with, for example, an Si concentration of not less than 1×10¹⁸ cm⁻³ and not more than 5×10¹⁹ cm⁻³, and a thickness of 6 μm), and an Si-doped n-type Al_{0.10}Ga_{0.90}N cladding layer (with, for example, an Si concentration of 1×10¹⁸ cm⁻³ and a thickness of 0.02 μm) are formed subsequently in this order on the above described arrangement. The Si-doped n-type GaN contact layer and the Si-doped n-type Al_{0.10}Ga_{0.90}N cladding layer are a first semiconductor layer 10. Note that, for the sake of convenience, the first semiconductor layer 10 may include a portion or all of the above-described buffer layers.

Next, as a light emitting layer 30, Si doped n-type Al_{0.11}Ga_{0.89}N barrier layers and GaInN well layers are stacked alternately in a thrice repeated pattern (a multi quantum well) on the above-described arrangement, and topped with a final multi-quantum-well Al_{0.11}Ga_{0.89}N barrier layer. In the Si doped n-type Al_{0.11}Ga_{0.89}N barrier layer, the Si concentration is, for example, set to not less than 1.1×10¹⁹ cm⁻³ and not more than 1.5×10¹⁹ cm⁻³. In the final Al_{0.11}Ga_{0.89}N barrier layer, the Si concentration is, for example, set to not less than 1.1×10¹⁹ cm⁻³ and not more than 1.5×10¹⁹ cm⁻³ with a thickness of, for example, 0.01 μm. A thickness of multi quantum well structure of this type is set to, for example, 0.75 μm. Thereafter, an Si doped n-type Al_{0.11}Ga_{0.89}N layer (with an Si concentration of, for example, not less than 0.8×10¹⁹ cm⁻³ and not more than 1.0×10¹⁹ cm⁻³, and a thickness of, for example, 0.01 μm) is formed. Note that a wavelength of the luminescent light in the light emitting layer 30 is, for example, not less than 370 nm and not more than 480 nm.

Further, as a second semiconductor layer 20, a non-doped Al_{0.11}Ga_{0.89}N spacer layer (with a thickness of, for example, 0.02 μm), an Mg doped p-type Al_{0.28}Ga_{0.72}N cladding layer (with an Mg concentration of, for example, 1×10¹⁹ cm⁻³ and a thickness of, for example, 0.02 μm), and an Mg doped p-type GaN contact layer (with an Mg concentration of, for example, 1×10¹⁹ cm⁻³ and a thickness of, for example, 0.4 μm), and a high-concentration Mg doped p-type GaN contact layer (with an Mg concentration of, for example, 5×10¹⁹ cm⁻³, and a thickness of, for example, 0.02 μm) are formed subsequently in this order.

Note that the above-described compositions, composition ratios, types of impurity, impurity concentrations and thickness are examples and various variations are possible.

Next, as shown in FIG. 1B, a second electrode 50 is selectively formed on a major surface 100b of the stacked body 100. Then, as shown in FIG. 1C, dry etching is performed on predetermined positions on the stacked body 100 to form a mesa structure.

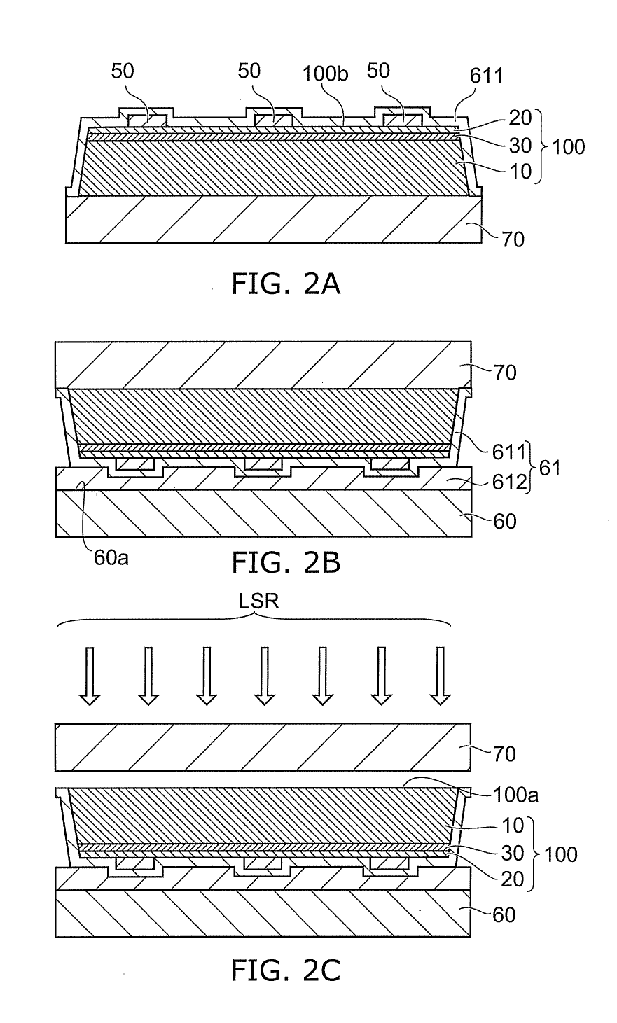

Next, as shown in FIG. 2A, a first metal 611 is formed so as to cover the major surface 100b of the stacked body 100 and the second electrodes 50. Next, as shown in FIG. 2B, a support substrate 60 with a second metal 612 formed thereon is prepared. Then, the second metal 612 formed on the major surface 60a of the support substrate 60 and the previously-manufactured first metal 611 on the growth-use substrate 70 side are set to oppose each other and adhered together.

Here, for the first metal 611, a stacked film having, for example, titanium (Ti), gold (Au) and gold-tin alloy (AuSn) stacked subsequently on the major surface 100b is used. Further, for the second metal 612, a stacked film having, for example, Ti and Au stacked subsequently on the major surface 60a is used. The result of bonding the first metal 611 and the second metal 612 is the bonded metal 61.

Next, as shown in FIG. 2C, the stacked body 100 is irradiated with laser light LSR from the growth-use substrate 70 side and laser liftoff is performed. As a result, the growth-use substrate 70 is separated from the major surface 100a of the stacked body 100.

Next, as shown in FIG. 3A, the stacked body 100 is etched at positions corresponding to boundary lines of the semiconductor light emitting devices. Here, for example, dry etching is used as the etching. Note that although FIG. 3A illustrates an etching state in which the stacked body is divided into three semiconductor light emitting devices, in reality the stacked body 100 is divided into a matrix of multiple semiconductor light emitting devices. The stacked body 100 is etched from the major surface 100a to the major surface 100b on the opposite side. As a result, the plurality of the light emitting regions 100R is formed.

Next, as shown in FIG. 3B, a protective film 80 is formed over all surfaces. For the protective film 80, SiO₂, for example, is used. Next, as shown in FIG. 3C, the protective film 80 is selectively removed. For example, a resist pattern R is formed on only the portions of the protective film 80 that are to be retained, and the remaining protective film 80 is removed with, for example, a fluoric acid, using the resist pattern R as a mask. As a result, portions of the surfaces of the light emitting regions 100R and portions between the plurality of light emitting regions 100R are exposed.

Next, the bonded metal 61 (the first metal 611 and the second metal 612) at the portions between the exposed plurality of light emitting regions 100R is etched. Here, the Ti included in the first metal 611 and the second metal 612 is etched using, for example, fluoric acid, and the Au is etched using, for example, a KI/I₂ mixture. As a result of the etching, portions of the support substrate 60 between the plurality of light emitting regions 100R are exposed. After the etching the resist pattern R is removed.

Next, as shown in FIG. 4A, the exposed portions of the light emitting region 100R and the support substrate 60 are subjected to anisotropic etching. For the anisotropic etching, wet etching with an alkaline solution, for example, is used. For the alkaline solution, potassium hydroxide (KOH) solution, tetramethyl ammonium hydroxide (TMAH), or ammonia hydroxide (NH₄OH), for example, is used.

In the embodiment, an example in which KOH solution is used will be described.

As a result of the anisotropic etching, the concave and convex portions 12p are formed at the surface of the light emitting region 100R, which is to say the exposed surface of the first semiconductor layer 10. Further, as a result of the anisotropic etching, in addition to the concave and convex portions 12p being formed, V-shaped grooves 60G are formed between the plurality of light emitting regions 100R in the major surface 60a of the support substrate 60.

The anisotropic etching is, for example, performed under the following conditions: 1 mole (mol)/liter (L) to 5 mol/L KOH solution heated to 80° C. for 15 to 20 minutes.

In alkaline etching with KOH solution or the like, anisotropic etching takes place along plane orientations of the GaN crystals (mainly [10-1-1]) with the result that the concave and convex portions 12p are formed with six-sided pyramid structures.

The concave and convex portions 12p are provided, for example, to increase the extraction efficiency of luminescent light from the light emitting layer 30, that is incident on the concave and convex portions 12p, or to change the angle of incidence. For this reason, it is preferable that the size of the concave and convex portions 12p is not less than the wavelength of the luminescent light within the crystal layer. In the embodiment, a depth of the concave portions of the concave and convex portions 12p is approximately 1 micrometer (μm) to 2 μm.

At the same time as the anisotropic etching, V-shaped grooves 60G of a predetermined angle are formed in the major surface 60a of the silicon support substrate 60.

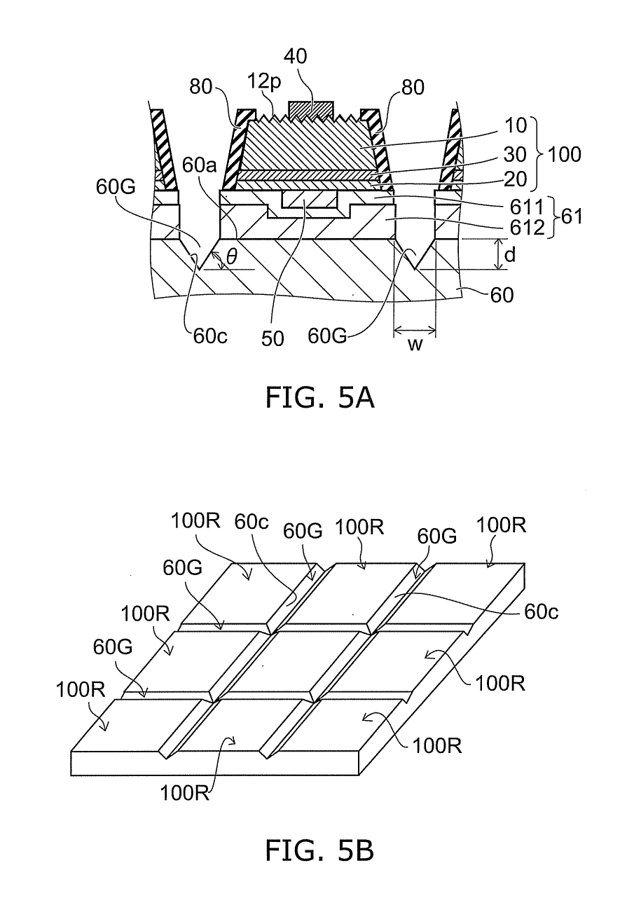

FIGS. 5A and 5B are schematic views illustrating the grooves.

FIG. 5A is a schematic cross-sectional view illustrating a cross-section of the grooves. FIG. 5B is a schematic perspective view illustrating a portion of the grooves.

The major surface 60a of the support substrate 60 is a (100) face of the silicon. Further, wall faces 60c of the groove 60G are the (111) face of the silicon.

In the etching of the silicon using the alkaline solution such as KOH solution or the like, an etching rate will differ according to the orientation. For example, the etching rate of silicon using KOH solution is 1500 nanometers (nm)/minute (min) to 2000 nm/min for the (100) face and (110) face and 3.0 nm/min to 4.0 nm/min for the (111) face. As a result of this difference in etching rate, the V-shaped grooves 60G are formed in the major surface 60a.

Note that the etching rate of the SiO₂ used as the protective film 80 with KOH solution is about 10 nm/min and thus the etching to form the concave and convex portions 12p and grooves 60G is largely unaffected.

As shown in FIG. 5A, an angle θ of the wall faces 60c of the grooves 60G with respect to the major surface 60a is about 55°. Further, a width w at the open side of the grooves 60G is, for example, 42 μm. Moreover, a depth d of the grooves 60G is, for example, 30 μm.

As shown in FIG. 5B, the grooves 60G are provided so as to intersect laterally and longitudinally on the major surface 60a of the support substrate 60. The regions surrounded by the grooves 60G are the light emitting regions 100R. Here, the width w of the grooves 60G at the open side is equal to a distance between two adjacent light emitting regions 100R.

In the embodiment, the concave and convex portions 12p and the grooves 60G are collectively formed by a single isotropic etching operation. Hence, a ratio of the depth of the concave portions of the concave and convex portions 12p to the depth d of the grooves 60G is equal to a ratio of the etching rate of the anisotropic etching of the light emitting regions 100R to an etching rate of the anisotropic etching of the support substrate 60.

For example, the etching rate of the GaN with the KOH solution is 50 nanometers (nm)/minute (min) to 100 nm/min. As described above, the etching rate of the (100) face of the silicon with KOH solution is 1500 nm/min to 2000 nm/min, and so, if a depth of the concave portions of the concave and convex portions 12p is “1”, a depth d of the grooves 60G will be from “15” to “40”.

Next, as shown in FIG. 4B, first electrodes 40 are formed on the first semiconductor layer 10 of the light emitting regions 100R. For the first electrodes 40, an aluminum (AI)/Ti/Au stacked film or a Ti/platinum (Pt)/Au stacked film, for example, is used. The first electrodes 40 are, for example, formed by a liftoff method whereby electrode material is formed over a resist pattern (not shown) and the resist pattern is removed.

Next, as shown in FIG. 4C, the support substrate 60 is ground to a predetermined thickness. In other words, a major surface 60b of the support substrate 60 which is on the opposite side to the major surface 60a is ground. A thickness of the support substrate 60 after grinding is thicker than the depth d of the grooves 60G. Specifically, the thickness is not more than 4 times, and preferably not more than 3 times the depth d of the grooves 60G. In the embodiment, the thickness of the support substrate 60 is from about 90 μm to 100 μm. Thereafter, the electrode film 51 is formed on, for example, the entire major surface 60b. For the electrode film 51, a Ti/Pt/Au multilayer film, for example, is used.

Next, as shown in FIG. 4D, the support substrate 60 is divided. Specifically, breaking is performed at positions of the grooves 60G formed in the support substrate 60. Because the grooves 60G are V-shaped, it is possible to divide the support substrate 60 by, for example, applying pressure to the support substrate 60 from the major surface 60b side to generate cracks that start at bottom portions (tip of the V-shape) of the grooves 60G on the major surface 60b side of the support substrate 60.

Since the support substrate 60 is pre-ground to the above-described thickness, the support substrate 60 can be precisely divided at the positions of the grooves 60G by performing breaking.

Dividing the support substrate 60 completes the semiconductor light emitting devices 110 formed by dividing arrangement into the respective light emitting regions 100R.

According to this method for manufacturing the semiconductor light emitting device 110, the grooves 60G used when breaking the support substrate 60 are collectively formed by the anisotropic etching at the time of forming the concave and convex portions 12p. As a result, there is no need to separately scribe the support substrate 60, and the manufacturing process can be simplified.

Also, because the grooves 60G are formed without scribing the support substrate 60, defects and dust in the support substrate 60 and the peeling of the bonded metal 61, which can occur easily during scribing, can be avoided. Hence, it is possible to manufacture the semiconductor light emitting device 110 having high reliability.

Further, since the grooves 60G are formed by anisotropic etching, a gap between any two adjacent light emitting regions 100R can be set to be narrower in comparison to when a scribe is provided separately between the two adjacent light emitting regions 100R.

In other words, when a scribe is provided between two adjacent light emitting regions 100R, the gap between two light emitting regions 100R must be made large enough to allow positioning of the tool that provides the scribe.

By contrast, when the grooves 60G are formed by anisotropic etching, the grooves can be positioned precisely by using the precision of photolithography. Hence, the gaps between two adjacent light emitting regions 100R can be narrowed, and it is possible to manufacture a greater number of semiconductor light emitting devices 110 from the support substrate 60 of the same size.

For example, when the scribe is used to divide the support substrate 60, a gap of about 100 μm is required between two adjacent light emitting regions 100R to form the scribe. On the other hand, when the grooves 60G are used, the gap between two adjacent light emitting regions 100R can be matched to the width w of the grooves 60G. Hence, about 50 μm is sufficient as a gap between the two adjacent light emitting regions 100R. Consequently, the number of semiconductor light emitting devices 110 that can be manufactured from the support substrate 60 can be about 10% higher than the number from a substrate of the same size.

Note also that although in the above described embodiment an example was described in which the sapphire was used as the growth-use substrate 70, the growth-use substrate 70 is not limited to sapphire. For example, a substrate including Si may be used as the growth-use substrate 70. When Si is used, it is easier to prepare larger growth-use substrate 70 in comparison than when sapphire is used. Hence, using a growth-use substrate 70 including Si makes it easier to manufacture a larger number of semiconductor light emitting devices 110 from a single growth-use substrate 70.

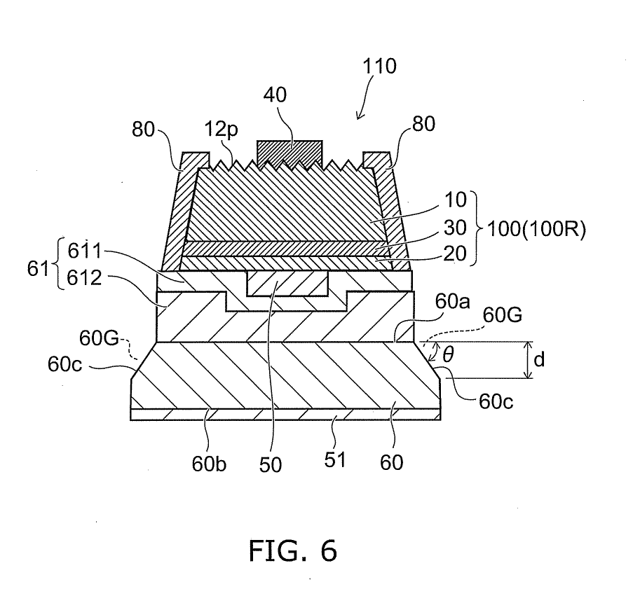

FIG. 6 is a schematic cross-sectional view illustrating a semiconductor light emitting device.

FIG. 6 illustrates the semiconductor light emitting device 110 manufactured by the manufacturing method according to the first embodiment. The semiconductor light emitting device 110 includes the light emitting region 100R, the first electrode 40, the second electrode 50, and the support substrate 60.

The light emitting region 100R includes a first semiconductor layer 10 of a first conductivity type, a second semiconductor layer 20 of a second conductivity type, and a light emitting layer 30 provided between the first semiconductor layer 10 and the second semiconductor layer 20. The light emitting region 100R is provided by dividing the stacked body 100 of the first semiconductor layer 10, the light emitting layer 30 and the second semiconductor layer 20.

The concave and convex portions 12p are provided on surfaces of the first semiconductor layer 10 of the light emitting regions 100R. As a result of the concave and convex portions 12p, the extraction efficiency for light emitted from the light emitting layer 30 to the exterior is improved. Further, the protective film 80 is provided on side faces of the light emitting region 100R.

The first electrode 40 contacts the first semiconductor layer 10. The first electrode 40 is, for example, an n-side electrode. The second electrode 50 contacts the second semiconductor layer 20. The second electrode 50 is, for example, a p-side electrode.

The light emitting region 100R is connected to the support substrate 60 via the bonded metal 61. The bonded metal 61 includes the first metal 611 provided on the second semiconductor layer 20 side of the light emitting region 100R, and the second metal 612 provided on the major surface 60a side of the support substrate 60. The first metal 611 and the second metal 612 are adhered together, thereby connecting the light emitting region 100R and the support substrate 60.

At upper portions of the side faces of the support substrate 60, a portion of the wall faces 60c of the grooves 60G is exposed. The wall faces 60c are provided so as to surround the periphery of the light emitting region 100R. As described above, the concave and convex portions 12p and the grooves 60G are formed by a single anisotropic etching operation. When the support substrate 60 is made of silicon, the angle θ of the wall faces 60c with respect to the major surface 60a is about 55°.

Further, a ratio of the depth of the concave portions of the concave and convex portions 12p to the depth d of the grooves 60G is equal to a ratio of the etching rate of the anisotropic etching of the light emitting regions 100R to an etching rate of the anisotropic etching of the support substrate 60.

### Second Embodiment

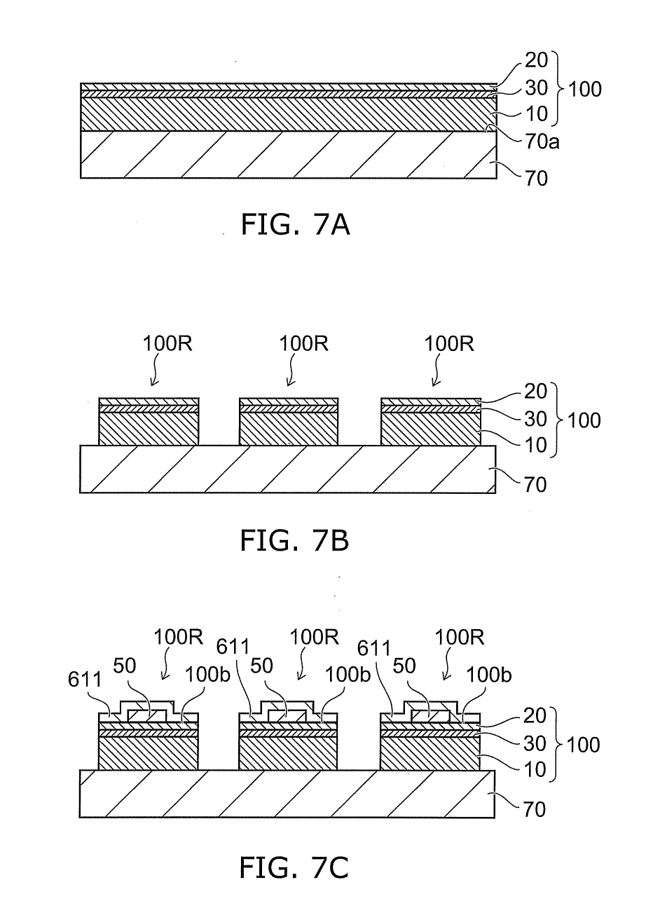

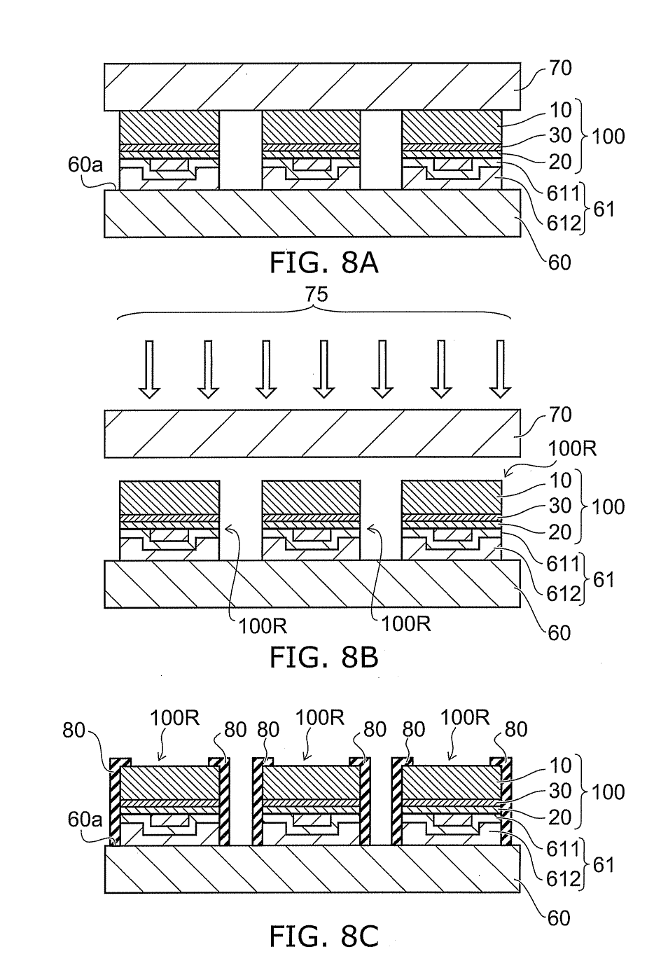

FIGS. 7A to 8C are schematic cross-sectional views illustrating a method for manufacturing a semiconductor light emitting device according to a second embodiment.

In the following, the description will focus on points that differ from the first embodiment.

First, as shown in FIG. 7A, after forming a buffer layer (not shown) on a major surface 70a of the growth-use substrate 70, which is made of, for example, sapphire, the stacked body 100 that includes the first semiconductor layer 10, light emitting layer 30 and the second semiconductor layer 20, is grown by crystalline growth. The configuration of the stacked body 100 is the same as that of the first embodiment.

Next, as shown in FIG. 7B, the stacked body 100 is divided into individual portions of the semiconductor light emitting device size. Specifically, photolithography and etching are, for example, performed on the stacked body 100 to divide the stacked body 100 to portions of a predetermined size. When divided to portions of the predetermined size, the stacked body 100 forms the light emitting regions 100R.

Next, as shown in FIG. 7C, the second electrodes 50 are selectively formed on the major surface 100b of each of the light emitting regions 100R. Then, the first metal 611 is formed so as to cover the second electrodes 50.

Next, as shown in FIG. 8A, the support substrate 60 with the second metal 612 formed thereon is prepared. The second metal 612 is selectively formed on the major surface 60a of the support substrate 60. The second metal 612 is selectively formed so as to match the individual semiconductor device formation positions.

Then, the second metal 612 formed on the major surface 60a of the support substrate 60 and the previously-manufactured first metal 611 on the growth-use substrate 70 side are set in opposition to each other and adhered together. Each of the first metal 611 and each of the second metal 612 are bonded to each other in an opposing state.

Next, as shown in FIG. 8B, laser liftoff is performed by irradiating the first semiconductor layer 10 of the light emitting region 100R with laser light LSR from the growth-use substrate 70 side. As a result, the growth-use substrate 70 is separated from the light emitting region 100R.

Next, as shown in FIG. 8C, the protective film 80 is formed so as to cover the individual light emitting regions 100R, leaving exposed a portion of the surface of each light emitting region 100R and the portions between the light emitting regions 100R.

Thereafter, the processes are the same as those shown in FIGS. 4B to 4D. Specifically, the exposed portions of the light emitting regions 100R and the support substrate 60 undergo anisotropic etching, the concave and convex portions 12p are formed on the surfaces of the light emitting regions 100R and V-shaped grooves 60G are formed in the exposed portions of the support substrate 60. Then the support substrate 60 is ground, the electrode films 51 are formed and breaking is performed to complete the individual semiconductor light emitting devices.

In the method for manufacturing the semiconductor light emitting device according to the second embodiment, the following effects are obtained over and above the effects obtained in the first embodiment.

Specifically, in the method for manufacturing a semiconductor light emitting device according to the second embodiment, the stacked body 100 is divided to form the individual light emitting regions 100R before adhering the support substrate 60. Hence the stresses that occur when the supporting substrate 60 is adhered and stresses that occur when the growth-use substrate 70 is separated can be mitigated.

In summary, because the contact area when adhering the support substrate 60 is small compared with the first embodiment, the stress that occurs when adhering the substrate 60 can be reduced. Also, because the contact area between the growth-use substrate 70 and the first semiconductor layer 10 is small compared with the first embodiment, the stress that occurs when separating the growth-use substrate 70 can be reduced.

As a consequence, the occurrences of peeling of the bonded metal 61 when separating the growth-use substrate 70 and defects in the light emitting regions 100R or the like can be suppressed.

Further, in the method for manufacturing a semiconductor light emitting device according to the second embodiment, selectivity of the materials of the bonded metal 61 can be improved compared with the first embodiment. Specifically, in the first embodiment, etching of the bonded metal 61 (the first metal 611 and the second metal 612) is performed with a portion of the surface of the light emitting region 100R in an exposed state (see FIG. 3C), and so in the etching it is necessary to use an etchant that etches the bonded metal 61 alone and does not etch the light emitting region 100R. Hence, the materials for the bonded metal 61 must be materials that can be etched using such an etchant.

By contrast, in the second embodiment, the first metal 611 and the second metal 612 are etched independently from the light emitting region 100R. Hence, in the second embodiment, materials for the first metal 611 and the second metal 612 can be selected without being subjected to the limitations on the etchant compared with the first embodiment.

### Third Embodiment

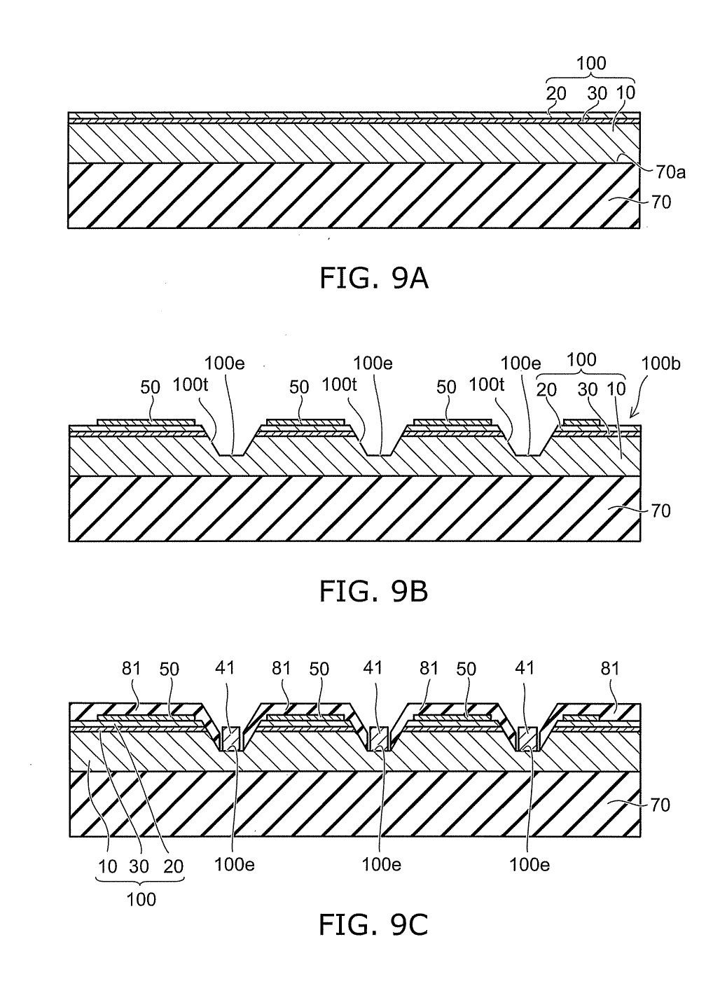

FIGS. 9A to 12 are schematic cross-sectional views illustrating a method for manufacturing a semiconductor light emitting device according to a third embodiment.

First, as shown in FIG. 9A, after forming a buffer layer (not shown) on the major surface 70a of the growth-use substrate 70 made of, for example, sapphire, the stacked body 100 including the first semiconductor layer 10, the light emitting layer 30 and the second semiconductor layer 20 is grown by crystalline growth. The configuration of the stacked body 100 is the same as that of the first embodiment.

Next, as shown in FIG. 9B, recesses 100t are formed in a portion of the stacked body 100. The recesses 100t are formed to reach from the major surface 100b of the stacked body 100 to the first semiconductor layer 10. Consequently, at bottoms of the recesses 100t, the first semiconductor layer 10 is exposed (exposed portions 100e).

To form the recesses 100t, a mask not shown here is formed on the second major surface 100b of the stacked body 100 and, for example, dry etching is performed. Specifically, openings are provided in the mask at portions where the recesses 100t are to be formed, and the stacked body 100 is removed from the second major surface 100b to the first semiconductor layer 10 by etching. As a result, the recesses 100t are formed.

Next, the second electrodes 50 that contact the second semiconductor layer 20 are formed. For the second electrodes 50, a stacked film of Ag/Pt, Ag/Ni that forms ohmic electrodes is first formed on the surface of the second semiconductor layer 20 with a film thickness of, for example, 200 nm, and cinder processing is then performed in an atmosphere of oxygen for 1 minute at a temperature of about 400° C. Next, a stacked film of, for example, Ti/Au/Ti with a thickness of, for example, 400 nm is formed on the ohmic electrodes for current diffusion, for use as a bonding metal to later-described pads 55 and as an adhering metal to a later-described insulating layer 81.

Next, as shown in FIG. 9C, the insulating layer 81 is formed so as to cover the second electrodes 50 and the recesses 100t. The insulating layer 81 is, for example, SiO₂, with a film thickness of 800 nm.

Next, to form n-side electrodes having ohmic characteristics, the insulating layer 81 is removed from the exposed portions 100e within the recesses 100t. A stacked film of, for example, Al/Ni/Au is then formed in the recesses 100t with a film thickness of, for example, 300 nm. As a result, contact portions 41 are formed.

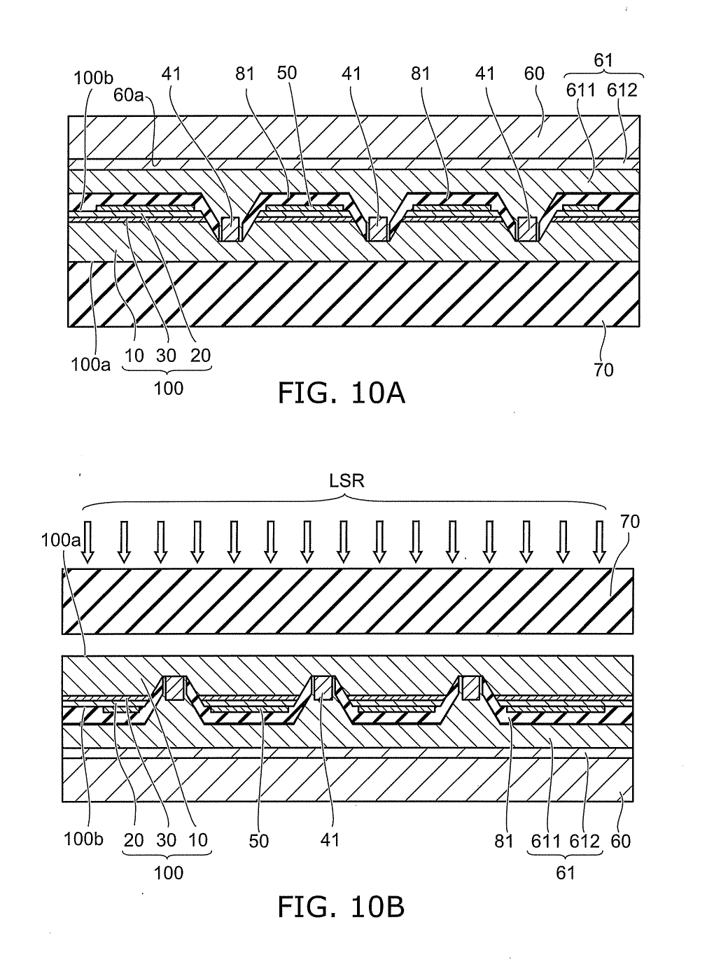

Next, as shown in FIG. 10A, the first metal 611 is formed with a film thickness of, for example, 800 nm over all exposed surfaces of the contact portions 41 and the insulating layer 81.

Next, the support substrate 60 made of, for example, silicon is prepared. The second metal 612 is provided on the major surface 60a of the support substrate 60 with a film thickness of, for example, 3 μm. Then, the first metal 611 and the second metal 612 are set to oppose each other and bonded. As a result, the support substrate 60 is bonded to the major surface 100b side of the stacked body 100.

Then, as shown in FIG. 10B, laser liftoff is performed by irradiating the stacked body 100 with laser light LSR from the growth-use substrate 70 side. As a result, the growth-use substrate 70 is separated from the major surface 100a of the stacked body 100.

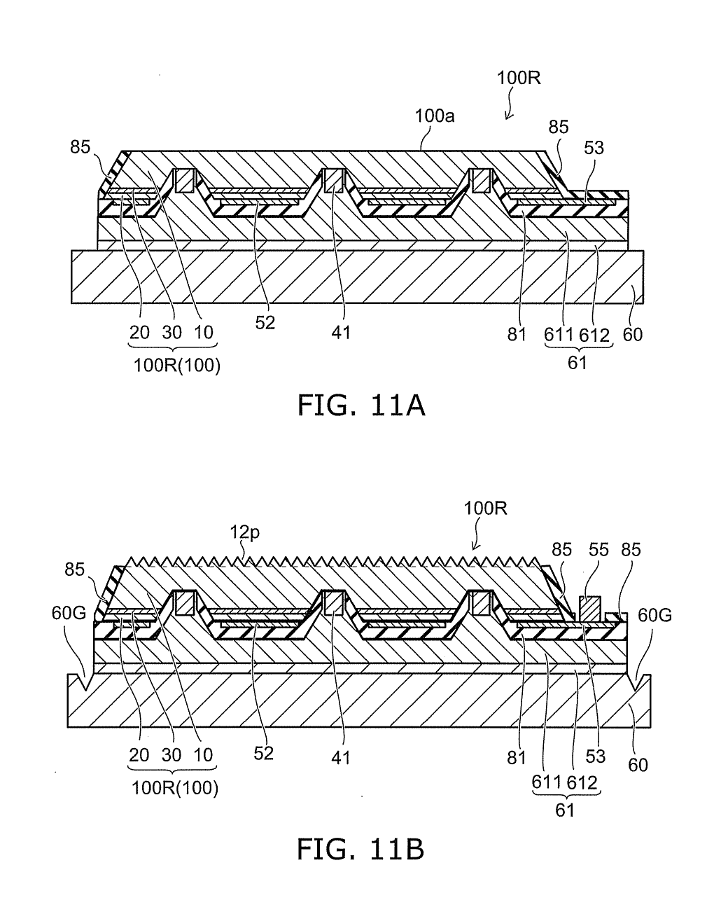

Next, as shown in FIG. 11A, a portion of the stacked body 100 is removed by dry etching to expose a portion of the second electrode 50 (extending portion 53). As a result of this etching, the stacked body 100 is divided into the individual light emitting regions 100R.

Next, the protective film 85 is formed over the entire surfaces of each light emitting region 100R with an opening provided at a portion of the surface of the light emitting region 100R and at a portion of the periphery of the light emitting region 100R. For the protective film 85, SiO₂ is, for example, used. A film thickness of the protective film 85 is, for example, 800 nm.

Next, the bonded metal 61 (the first metal 611 and the second metal 612) at the periphery of the light emitting region 100R is etched to expose a portion of the support substrate 60.

Next, as shown in FIG. 11B, the exposed surface of the light emitting region 100R is subjected to anisotropic etching, with the protective film 85 including the opening as a mask. For the anisotropic etching, wet etching with, for example, an alkaline solution is used. For the alkaline solution, KOH solution or TMAH is, for example, used. In the embodiment, KOH solution is used.

As a result of the anisotropic etching, the concave and convex portions 12p are formed at the surface of the light emitting region 100R, which is to say the exposed surface of the first semiconductor layer 10. Further, as a result of the anisotropic etching, in addition to the concave and convex portions 12p being formed, the V-shaped grooves 60G are formed at the exposed portions of the support substrate 60.

Next, a portion of the protective film 85 covering the extending portion 53 is removed, and the pad 55 is formed in the region. For the pad 55, a stacked film of, for example, Ti/Au is used. A film thickness of the pad 55 is, for example, 800 nm. Bonding wire is connected to the pad 55. To improve the bonding characteristics, it is preferable that, for example, Au is formed thickly (for example, to a thickness of 10 μm) by plating on the surface of the pad 55.

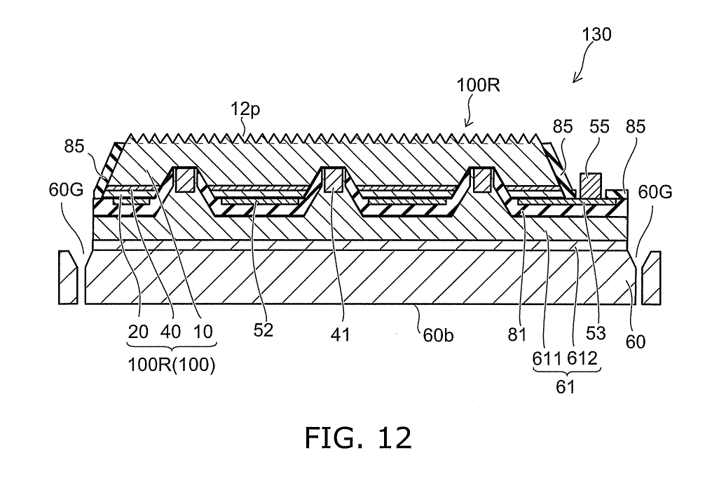

Next, as shown in FIG. 12, the support substrate 60 is divided. Specifically, breaking is performed at positions of the grooves 60G formed in the support substrate 60. Because the grooves 60G are V-shaped, it is possible to divide the support substrate 60 by, for example, applying pressure to the support substrate 60 from the major surface 60b side to generate cracks that start at bottom portions (tip of the V-shape) of the grooves 60G on the major surface 60b side of the support substrate 60.

Thereby, a semiconductor light emitting device 130 is completed.

The semiconductor light emitting device 130 manufactured in the manner described above does not have the first electrode 50 provided on the light extraction surface where the concave and convex portions 12p of the light emitting region 100R are formed. Hence, it is possible to extract light efficiently from the entire surface of the light extraction surface.

As described above, according to the embodiment, a method for manufacturing a semiconductor light emitting device can be provided that offers improvement in reliability and manufacturing yield.

Note also that although embodiments and variations have been described above, the invention is not limited to these. For example, although in each of the above-described embodiments, the first conductivity type was described as being n-type and the second conductivity type as being p-type, the first conductivity type may be p-type and the second conductivity type may be n-type. Also in the above described embodiments, when constituent elements are appropriately added, removed or changed in design by a person skilled in the art, or the characteristics of the various embodiments are appropriately combined; provided that the resulting configuration does not depart from the spirit of the invention, it falls within in the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a semiconductor light emitting device comprising:
forming a plurality of light emitting regions on a major surface of a support substrate;
forming V-shaped grooves by anisotropic etching between the plurality of light emitting regions in the major surface of the support substrate; and
dividing the support substrate at positions of the grooves to separate the light emitting regions.

2. The method according to claim 1, wherein, as well as the grooves being formed, concave and convex portions are formed on a surface of each of the light emitting regions by the anisotropic etching.

3. The method according to claim 2, wherein a ratio of a depth of concave portions of the concave and convex portions to a depth of the grooves is equal to a ratio of an etching rate of the anisotropic etching of the light emitting regions to an etching rate of the anisotropic etching of the support substrate.

4. The method according to claim 1, wherein the anisotropic etching is performed using an alkaline solution.

5. The method according to claim 1, wherein the support substrate is made of silicon.

6. The method according to claim 5, wherein the major surface is a (100) face of the silicon, and
wall faces of the grooves are (111) faces of the silicon.

7. The method according to claim 1, wherein a width of the grooves on an open side is equal to a distance between two adjacent light emitting regions.

8. The method according to claim 1, wherein the forming the light emitting regions includes
forming a stacked body having a first semiconductor layer, a light emitting layer and a second semiconductor layer stacked subsequently on a growth-use substrate,
adhering the support substrate to the stacked body, and
separating the growth-use substrate from the stacked body.

9. The method according to claim 8, wherein, in the separating the growth-use substrate, the growth-use substrate is separated from the stacked body using energy from laser light.

10. The method according to claim 8, wherein the growth-use substrate includes sapphire.

11. The method according to claim 8, wherein the growth-use substrate includes silicon.

12. The method according to claim 1, wherein the light emitting regions include a nitride semiconductor.

13. The method according to claim 1, wherein, in the dividing the support substrate at the positions of the grooves, the dividing is performed after reducing a thickness of the support substrate.

14. A method for manufacturing a semiconductor light emitting device, comprising:
forming a plurality of light emitting regions on a major surface of a support substrate made of silicon, the major surface being a (100) face;
exposing the major surface of the support substrate between the plurality of light emitting regions;
forming concave and convex portions on a surface of each of the light emitting regions by anisotropic etching with an alkaline solution, and forming V-shaped grooves with (111) face walls in the support substrate between the plurality of light emitting regions on the major surface of the support substrate by the anisotropic etching with the alkaline solution; and
dividing the support substrate at positions of the grooves to separate the light emitting regions.

15. The method according to claim 14, wherein the forming the light emitting region includes
forming a stacked body having a first semiconductor layer, a light emitting layer and a second semiconductor layer stacked subsequently on a growth-use substrate,
adhering the support substrate to the stacked body, and
separating the growth-use substrate from the stacked body.

16. The method of claim 15, wherein, in the separating the growth-use substrate, the growth-use substrate is separated from the stacked body using energy from laser light.

17. The method according to claim 14, wherein, the light emitting regions include a nitride semiconductor.
